(19) United States
(12) Patent Application Publication
(10) Pub. No.: US 2026/0354067 A1
(43) Pub. Date: Nov. 5, 2026

(54) METHODS OF FORMING AND USING TOPOLOGICALLY ETCH-SELECTIVE MATERIAL

(71) Applicant: ASM IP Holding B.V., Almere (NL)

(72) Inventors: Taishi Ebisudani, Tokyo (JP); Miguel Sérgio De Abreu Neto, Tokyo (JP); Miftah Faried, Tama-shi (JP); Hiroo Sekiguchi, Tokyo (JP); Hiroshi Kou, Tokyo (JP)

(21) Appl. No.: 19/662,504

(22) Filed: Apr. 29, 2026

Related U.S. Application Data
(60) Provisional application No. 63/798,647, filed on May 2, 2025.

(51) Int. Cl. H10P 50/00; H01J 37/32; H10P 14/60; H10P 50/24; H10P 50/64; H10P 76/40

(52) U.S. Cl. CPC H10P 50/695; H01J 37/32146; H10P 14/6336; H10P 50/242; H10P 50/646; H10P 50/692; H10P 76/405; H10P 76/4085; H01J 2237/3321

(57) ABSTRACT

Methods of forming topologically etch-selective material are disclosed. Exemplary methods include forming a layer overlying the substrate and anisotropically treating the layer to form the topologically etch-selective material. Exemplary methods can further include selectively removing portions of the topologically etch-selective material. Structures formed using the methods and systems for performing the methods are also disclosed.

### CROSS-REFERENCE TO RELATED APPLICATIONS

This application claims priority to U.S. Provisional Patent Application Ser. No. 63/798,647 filed May 2, 2025 and titled METHODS OF FORMING AND USING TOPOLOGICALLY ETCH-SELECTIVE MATERIAL, the disclosure of which is hereby incorporated by reference in its entirety.

### FIELD

The present disclosure generally relates to methods and systems for forming patterned structures on a surface of a substrate. More particularly, examples of the disclosure relate to methods that include formation of topologically etch-selective material, systems for performing such methods, and structures formed using the methods.

### BACKGROUND OF THE DISCLOSURE

During the manufacture of electronic devices, such as semiconductor devices and the like, fine patterns of features can be formed on a surface of a substrate by patterning the surface of the substrate with masking material and removing material from unmasked regions of the substrate surface using, for example, wet etch and/or dry etch processes. Photoresist is often used as the masking material.

A photoresist pattern can be formed by coating a layer of photoresist onto a surface of the substrate, masking the surface of the photoresist, exposing the unmasked portions of the photoresist to radiation, such as ultraviolet light or an electron beam, and removing a portion (e.g., the unmasked or masked portion) of the photoresist, while leaving a portion (e.g., the other of the unmasked or masked portion) of the photoresist on the substrate surface. Once the photoresist is patterned, the patterned photoresist can be used as a template for etching material on the substrate surface in regions in which the photoresist was removed to form a transferred pattern in a layer underlying the photoresist. After etching of the underlying layer, remaining photoresist can be removed.

As a size of features decreases, traditional photoresist techniques may not be suitable to form patterns of desired size. In such cases, multiple patterning techniques can be used to allow for patterning and etching of features that can be smaller than the exposure resolution of the photolithography process. A multiple patterning technique can include forming a spacer about patterned features (e.g., patterned photoresist), removing the patterned features to form patterned structures, and using the patterned structures as a mask during a subsequent etch.

Although such techniques may work relatively well in some applications, removing spacer material between patterned structures generally becomes increasingly difficult as a pitch of the patterned structures decreases. This can be particularly true when anisotropic dry etch processes are used because charges can build up on a surface of the substrate. In addition, traditional techniques to deposit material for a spacer can result in uneven or non-conformal films that include an overhang of material at a top surface of the patterned features. Such overhang may result in undesired variation in a pattern that is transferred using the spacers as a template. Accordingly, improved methods of forming patterned structures on a surface of a substrate are desired. Further, improved device structures, which include the patterned structures, are also desired. Systems for performing the method are also desired.

Any discussion of problems and solutions set forth in this section has been included in this disclosure solely for the purpose of providing context for the present disclosure and should not be taken as an admission that any or all of the discussion was known at the time the invention was made.

### SUMMARY OF THE DISCLOSURE

Various embodiments of the present disclosure relate to methods of forming patterned structures on a surface of a substrate, to the structures formed, and to systems for forming the patterned structures. The patterned structures can be used in the formation of devices, such as semiconductor devices or other devices.

While the ways in which various embodiments of the present disclosure address drawbacks of prior methods and systems are discussed in more detail below, in general, various embodiments of the disclosure provide improved methods of forming patterned structures by forming topologically etch-selective material. Methods described herein that include formation of topologically etch-selective material allow for formation of patterned structures with a relatively small pitch, using a relatively fast etch process, and/or allow for use of an isotropic etch, whereas prior techniques may have desirably used an anisotropic etch. In addition, methods described herein can be used to reduce overhang in initially deposited material and thereby increase a resolution of pattern transfer.

In accordance with examples of the disclosure, a method including formation of topologically etch-selective material is disclosed. An exemplary method includes providing a substrate comprising at least one feature comprising a top, a bottom, and a sidewall therebetween, conformally depositing a group 13 metal oxide over the at least one feature, and anisotropically treating the group 13 metal oxide. In accordance with various examples, the step of anisotropically treating includes providing a nitrogen-containing reactant to a reaction chamber, providing a first plasma power having a first frequency and a first power within the reaction chamber for a first plasma power pulse, and providing a second plasma power having a second frequency and a second power within the reaction chamber for a second plasma power pulse, wherein the step of treating forms the topologically etch-selective material. In accordance with aspects of these examples, the second frequency is less than the first frequency. In accordance with further aspects, the steps of providing the first plasma power and providing the second plasma power substantially coincide (i.e., steps begin and/or end at about substantially the same time). In accordance with yet further aspects, the first power is greater than the second power. In accordance with yet additional aspects, the second power is pulsed on and off (or from high to low) at a duty cycle between about 30 percent and about 70 percent for a plurality of cycles. A frequency of the plurality of cycles can be between, for example, about 1 kHz and about 30 kHz. In accordance with further aspects, the step of conformally depositing the group 13 metal oxide incudes (e.g., cyclically) providing a group 13 metal precursor and providing an oxygen-containing reactant. Exemplary methods can further include etching the topologically etch-selective material to selectively remove the topologically etch-selective material from the top and the bottom, relative to the sidewall. In some cases, the step of etching the topologically etch-selective material includes removing overhang material from a top of the feature. In accordance with various aspects, the step of etching can be or include an isotropic etch process. In accordance with yet additional aspects, the method includes providing a dilution gas during the steps of conformally depositing the group 13 metal oxide and anisotropically treating the group 13 metal oxide. As set forth in more detail below, to obtain desired pattern transfer, a flowrate of the dilution gas during the anisotropically treating the group 13 metal oxide is less than a flowrate of the dilution gas during the conformally depositing the group 13 metal oxide.

In accordance with further embodiments of the disclosure, a structure is provided. The structure can be formed according to a method as set forth herein. The structure can include a substrate and one or more patterned structures formed thereon or therein.

In accordance with yet additional examples of the disclosure, a system is provided. As described in more detail below, the system can include a controller configured to perform a method and/or form a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one embodiment of the disclosure.

FIG. 2 illustrates a timing sequence in accordance with at least one embodiment of the disclosure.

FIG. 3 illustrates another timing sequence in accordance with at least one embodiment of the disclosure.

FIGS. 4-10 illustrate structures in accordance with exemplary embodiments of the disclosure.

FIG. 11 illustrates a reactor system in accordance with at least one embodiment of the disclosure.

FIG. 12 illustrates another reactor system in accordance with at least one embodiment of the disclosure.

FIG. 13 illustrates removal of overhang in accordance with further examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particularly disclosed embodiments described below.

The present disclosure generally relates to methods of forming patterned structures on a surface of a substrate, to device structures including the patterned structures, and to systems for performing the methods and/or forming the device structures. The patterned structures can be used as an etch mask or as patterned features for formation of a next set of patterned structures. As described in more detail below, exemplary methods can be used to form structures suitable for forming electronic devices.

In this disclosure, gas may include material that is a gas at normal temperature and pressure, a vaporized solid and/or a vaporized liquid, and may be constituted by a single gas or a mixture of gases, depending on the context. A gas other than the process gas, e.g., a gas introduced without passing through a gas distribution assembly, such as a showerhead, other gas distribution device, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. In some cases, the terms precursor and reactant can be used interchangeably.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various features, such as recesses, lines, and the like formed within or on at least a portion of a layer of the substrate. By way of particular examples, a substrate can include bulk semiconductor material and/or a layer to be etched.

In some embodiments, film refers to a layer extending in a direction perpendicular to a thickness direction to cover an entire target or concerned surface, or simply a layer covering a target or concerned surface. In some embodiments, a layer refers to a structure having a certain thickness formed on a surface or a synonym of film or a non-film structure. A layer can be continuous or noncontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers.

A feature can refer to a protrusion above a surface of a substrate or a recess that extends into the substrate. A protrusion can be a pillar, line, or the like. A recess can be a via, trench, or the like. In some cases, the terms patterned features and patterned structures can be used interchangeably.

In this disclosure, continuously can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments. For example, a reactant and/or an inert gas can be supplied continuously during two or more steps and/or deposition cycles and/or treatment cycles of a method.

The term cyclic deposition process or cyclical deposition process can refer to the sequential introduction of precursors (and/or reactants) and/or pulsing of plasma power into or within a reaction chamber to deposit a layer over a substrate and includes processing techniques, such as atomic layer deposition (ALD), cyclical chemical vapor deposition (cyclical CVD), hybrid cyclical deposition processes that include an ALD component and a cyclical CVD component, and plasma-enhanced variations thereof.

As used herein, the term atomic layer deposition (ALD) may refer to a vapor deposition process in which deposition cycles, preferably a plurality of consecutive or continuous deposition cycles, are conducted in a process chamber. Typically, during each cycle, a precursor is introduced and may be chemisorbed to a deposition surface (e.g., a substrate surface or a previously deposited underlying surface, such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Purging steps may be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms, such as chemical vapor atomic layer deposition, when performed with alternating pulses of precursor(s), reactant(s), and purge (e.g., inert carrier) gas(es). PEALD refers to an ALD process, in which a plasma is applied during one or more of the ALD steps.

As used herein, the term purge may refer to a procedure in which an inert or substantially inert gas is provided to a reactor chamber in between two pulses of gases that might otherwise react with each other. For example, a purge may be provided between a precursor pulse and a plasma pulse, thus avoiding or at least reducing gas phase interactions between the precursor and an activated reactant. It shall be understood that a purge can be effected either in time or in space, or both. For example, in the case of temporal purges, a purge step can be used, e.g., in the temporal sequence of providing a first precursor to a reactor chamber, providing a purge gas to the reactor chamber, and providing a second precursor or reactant to the reactor chamber, wherein the substrate on which a layer is deposited does not move. In the case of spatial purges, a purge step can, for example, take the following form: moving a substrate from a first location to which a first precursor is supplied, through a purge gas curtain, to a second location to which a second precursor is supplied.

As used herein, metal oxide refers to a material that includes at least one metal and oxygen. A metal oxide can be represented by the formula MOₓ, where M represents a metal (e.g., TiO₂). In some cases, the metal oxide may not be or include stoichiometric metal oxide. In some cases, the metal oxide can include other elements, such as carbon, nitrogen, hydrogen, or the like. Exemplary metals include group 13 metals, such as titanium.

As used herein, the term overlap can mean coinciding with respect to time and within a reaction chamber. For example, when two or more plasma power periods overlap, there is a period of time in which power for each of the two or more plasma power periods is provided to a reaction chamber. Similarly, with regard to gas pulse periods, such as precursor pulse periods and reactant pulse periods, two or more gas pulse periods can overlap when gas from the respective pulse periods is within the reaction chamber or provided to the reaction chamber for a period of time.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. The terms comprising, including, constituted by and having refer independently to typically or broadly comprising, comprising, consisting essentially of, or consisting of in some embodiments. In this disclosure, any defined meanings do not necessarily exclude ordinary and customary meanings, in some embodiments.

Although a number of example materials are given throughout the embodiments of the current disclosure, it should be noted that the chemical formulas given for each of the example materials should not be construed as limiting. Unless otherwise noted, the non-limiting example materials given should not be limited by a given example stoichiometry.

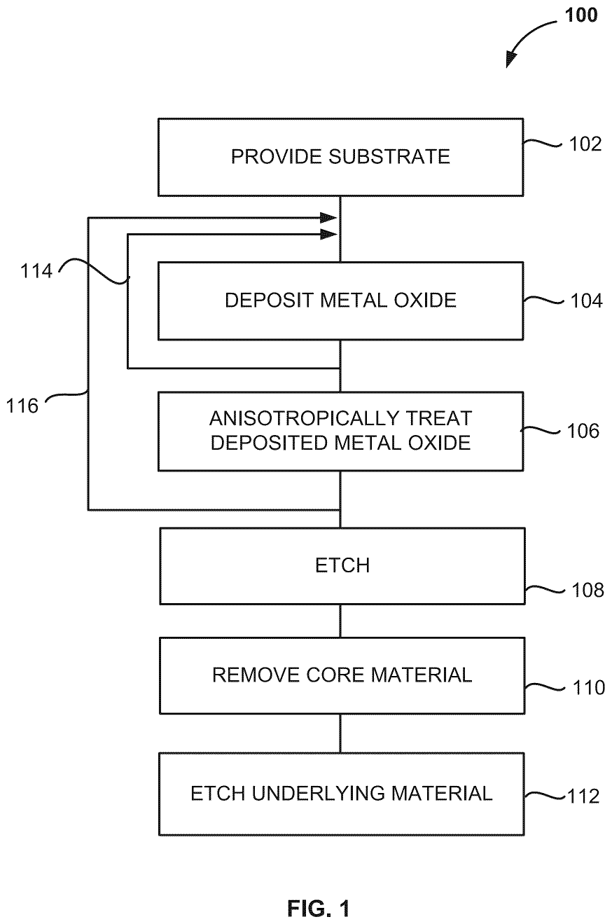

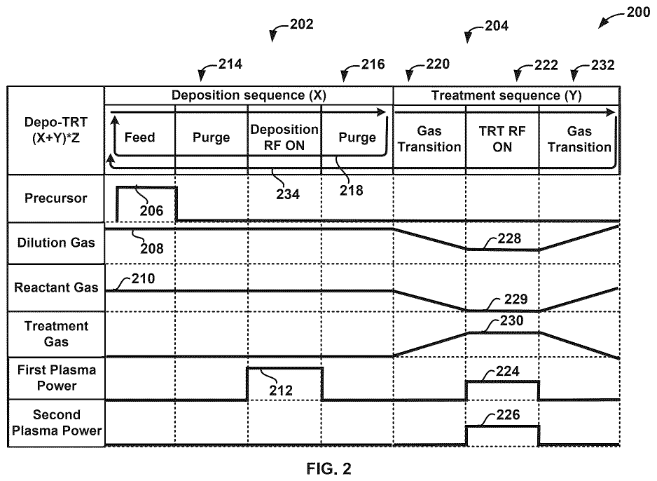

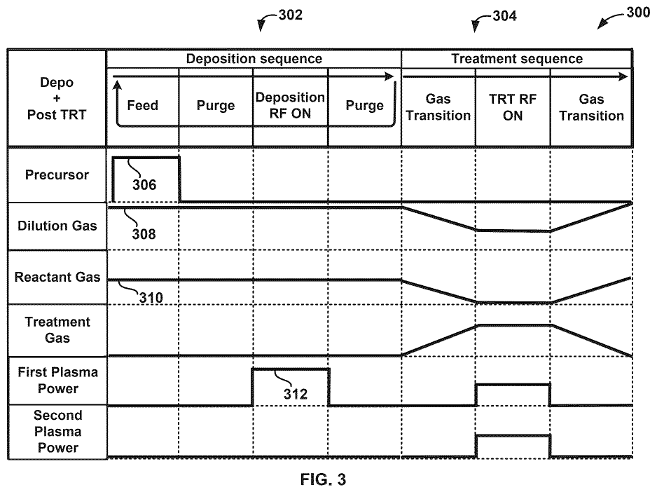

Turning now to the figures, FIG. 1 illustrates a method 100 including formation of topologically etch-selective material in accordance with examples of the disclosure. Method 100 can be used for a variety of purposes, such as, for example, forming patterned structures (e.g., using a multiple patterning process). As illustrated, method 100 includes the steps of providing a substrate, the substrate comprising at least one feature (step 102), depositing a metal oxide (step 104), anisotropically treating deposited metal oxide (step 106), etching (step 108), removing mandrels/core material (step 110), and etching an underlayer (step 112). Although illustrated with steps 102-112, exemplary methods need not include all such steps but rather can include any subset of the steps. FIGS. 2 and 3 illustrate timing sequences 200 and 300 suitable for steps 104 and 106 of method 100.

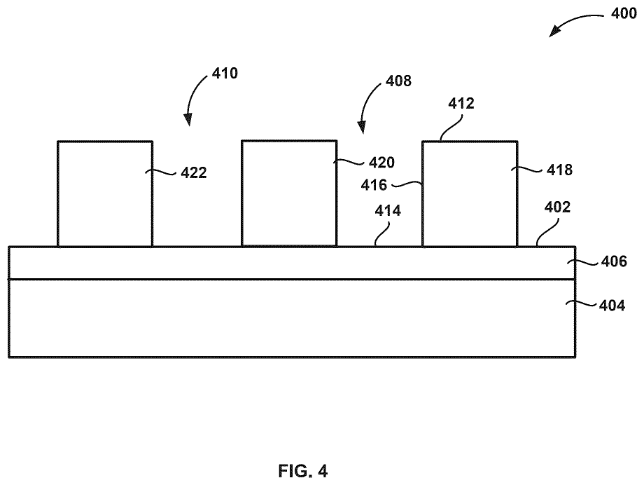

During step 102, a substrate comprising a surface comprising at least one feature is provided (e.g., within a reaction chamber of a reactor system). An exemplary substrate 400 for use during step 102 is illustrated in FIG. 4. In this example, the substrate includes a first layer or bulk material 404, a second layer 406 (e.g., a layer to be etched), and a surface 402, including patterned features 408, 410. First layer or bulk material 404 can include, for example, silicon or other semiconductor material; second layer 406 can include, for example, one more materials having etching selectivity against materials (e.g., metal oxides) used to form patterned structures. With reference to feature 408, one or more features can include a top 412, a bottom 414, and a sidewall 416 (e.g., spanning) therebetween. Features 408, 410, can be recesses, trenches, vias, or the like and can be defined, at least in part, by mandrels 418, 420, 422. Mandrels 418, 420, 422 can be formed of or include, for example, one or more of photoresist, carbon hardmask material, amorphous silicon, amorphous carbon, polysilicon, or the like.

Returning again to FIG. 1, the reaction chamber used during step 102 and/or other steps (e.g., steps 104, 106, 108) of method 100 can be or include a reaction chamber of a chemical vapor deposition reactor system configured to perform a cyclical deposition process. The reaction chamber can be a standalone reaction chamber or part of a cluster tool. Exemplary reaction chambers suitable for use with step 102 are described in more detail below.

Step 102 can include heating the substrate to a desired deposition temperature within the reaction chamber. In some embodiments of the disclosure, step 102 includes heating the substrate to a temperature of less than 400 °C. For example, in some embodiments of the disclosure, heating the substrate to a deposition temperature may comprise heating the substrate to a temperature between approximately 50 °C and approximately 400 °C or between about 20 °C and about 250 °C or between about 40 °C and about 220 °C. In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr or between about 1.5 Torr and 10 Torr. In some cases, a pressure within the reaction chamber is greater than 400 Pa or between greater than 400 Pa and about 500 Pa or between about 100 Pa and about 500 Pa or between about 200 Pa and about 400 Pa during step 102 and/or steps 104-108.

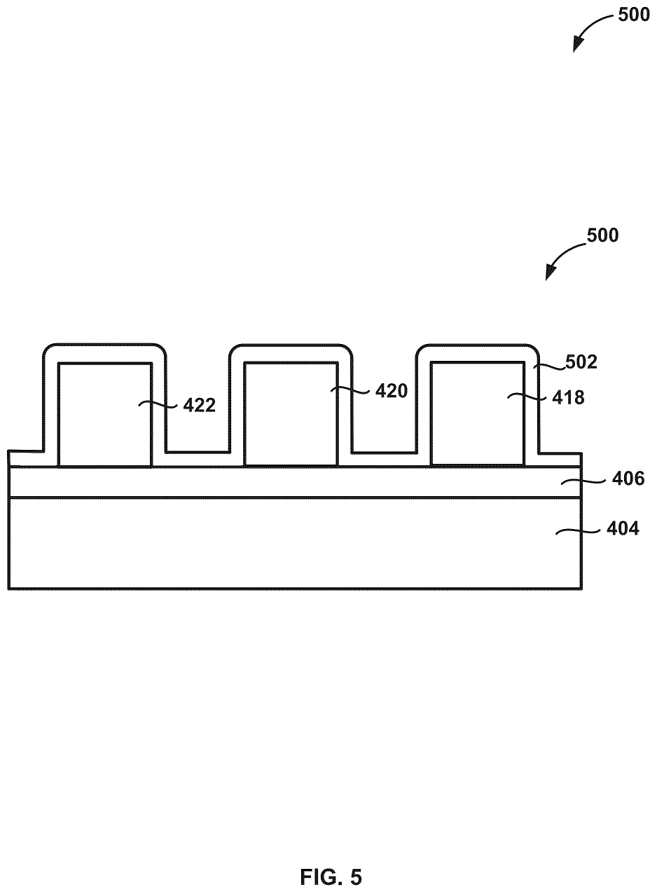

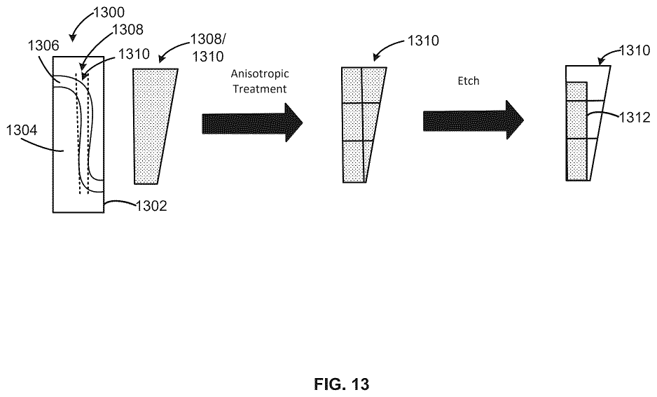

During step 104, a layer (e.g., layer 502, illustrated in FIG. 5) is (e.g., conformally or substantially conformally) formed overlying the substrate provided in step 102 to form structure 500. In some cases, the layer deposited during step 104 may include an overhang, as described in more detail below in connection with FIG. 13. Layer 502 can be or include, for example, a metal oxide, such as a group 13 metal oxide. Layer 502 can be relatively thin, e.g., less than about 20 nm. Layer 502 can exhibit a high etch selectivity, relative to layer 406.

In accordance with examples of the disclosure, step 104 includes providing a group 13 metal precursor and providing an oxygen-containing reactant. With reference to FIG. 2, timing sequence 200 that includes a deposition sequence 202 and a treatment sequence 204 is illustrated. Timing sequence 300, illustrated in FIG. 3, similarly includes a deposition sequence 302 and a treatment sequence 304. Deposition sequence 202 and deposition sequence 302 can be the same or similar and both are suitable for use as step 104 of method 100.

In the illustrated examples, deposition sequence 202 is a cyclical process that includes a precursor provision step 206, a dilution gas provision step 208, a reactant gas provision step 210, and a first plasma power provision step 212. Deposition sequence 302 similarly includes a precursor provision step 306, a dilution gas provision step 308, a reactant gas provision step 310, and a first plasma power provision step 312. Steps 306-312 can be the same or similar to steps 206-212. For brevity, a separate description of steps 306-312 is omitted.

During step 206, a group 13 metal precursor is provided (e.g., to the reaction chamber) for a metal precursor pulse. Exemplary group 13 metal precursors can include metal alkoxide and/or alkylamino compounds. The group 13 metal precursor can include a titanium. For example, a titanium precursor can be at least one compound selected from titanium alkoxide and alkylamino titanium. By way of particular examples, the precursor can be or include one or more of Ti(OR)₄ wherein R is independently CₓH_{y} (x=0, 1, 2, 3, 4, or 5, y=2x+1), and each R can be different (e.g., Ti(OCH₃)₂(OC₂H₅)(OC₃H₇)); Ti(NR₂)₄ wherein R is independently CₓH_{y} (x=0, 1, 2, 3, 4, or 5, y=2x+1), and each R can be different (e.g., Ti(N(CH₃)(C₂H₅))₄). A precursor for a metal oxide other than titanium oxide can also be selected from any suitable compounds. In general, an alkylamino precursor, such as tetrakis-dimethylaminotitanium (TDMAT), can provide a higher film growth rate than does an alkoxy precursor, such as titanium tetraisopropoxide (TTIP), because a precursor having a smaller molecular size, such as TDMAT, tends to have less steric hindrance, so as to have more adsorption sites as compared with a precursor having a greater molecular size, such as TTIP. A precursor with a carrier gas flowrate may be in a range of about 500 to about 5000 sccm. A duration of step 206, 306 can range from about 0.05 to about 5 seconds.

During step 208 a dilution gas is optionally provided to the reaction chamber. Exemplary dilution gases include argon, helium, other inert gas, or mixtures thereof. A flowrate of the dilution gas can be between, for example, about 1 SLM and about 20 SLM. In some cases, the dilution gas can also be a carrier gas used to provide the precursor during precursor pulse 206. As illustrated, step 208 can begin prior to step 206.

During step 210, at least one reactant is provided to the reaction chamber. Exemplary reactants include oxygen. Exemplary reactants that include oxygen include, for example, O₂, O₃, CO, CO₂, N₂O, N₂O₂, NO₂, mixtures thereof, or the like. In some cases, the providing at least one reactant includes providing an oxygen-containing reactant and providing a nitrogen-containing reactant. The oxygen-containing reactant can include, for example, O₂, O₃, CO, CO₂, N₂O, N₂O₂, NO₂, mixtures thereof, or the like. The nitrogen-containing reactant can include, for example, N₂, NH₃, N₂H₂, N₂O, N₂O₂, NO₂, mixtures thereof, or the like. A reactant can be provided continuously during (e.g., before, during, and after) one or more deposition cycles 202 and treatment cycles 204, 304. A reactant gas flowrate may be in a range of about 100 to about 10000 sccm. Further, as illustrated, step 210 can begin prior to step 206.

During step 212, a first plasma power is provided within the reaction chamber for a first plasma power pulse. The first plasma power has a first frequency and a first power.

By way of examples, the first frequency can be greater than 1 MHz or greater than 10 MHz or between about 10 MHz and about 100 MHz. The first power can be between about 50 W and about 1000 W or between about 100 W and about 500 W. A duration of the first plasma power pulse can be between about 0.1 and about 10 seconds or between about 0.2 and about 0.5 seconds.

Deposition sequence 202 can include one or more purge steps 214, 216. In the illustrated example, purge steps 214 and 216 include flowing of the dilution gas and the one or more reactants.

Steps 206-216 can be repeated as illustrated by loop 218 and loop 114. For example, steps 206-216 can be repeated from 0 to about 50 or about 1 to about 20 times to form a desired thickness of layer 502 before proceeding to step 106/treatment sequence 204.

Once a desired number of cycles 218 are performed, sequence 200 proceeds to treatment sequence 204. During step 106/treatment sequence 204, the (e.g., group 13 metal oxide) layer is treated to form the topologically etch-selective material. Treatment sequence 204 can include a first gas transition step 220, a plasma treatment step 222, and a second gas transition step 232. Treatment sequence 204 can be used as loop 116 to anisotropically treat the (e.g., group 13) metal oxide deposited using deposition sequence 202.

Treatment sequence 204 (i.e., anisotropically treating) can begin with gas transition step 220. During gas transition step 220, a flowrate of the one or more reactant gases provided during step 210 is reduced or ceased, a flowrate of a treatment gas is initiated or increased, and a flowrate of the dilution gas provided during step 208 can be decreased. For example, the flowrate of the one or more reactant gases can be reduced to 0. The flowrate of the treatment gas can be increased from, for example, 0 to, for example, about 20 SLM. The flowrate of the dilution gas can be reduced to maintain a desired chamber pressure—e.g., by keeping a total flowrate of gas to the reaction chamber about the same. The treatment gas provided during step 220 can be a nitrogen-containing reactant. The nitrogen-containing reactant can be or include a nitrogen-containing reactant as described above. A duration of gas transition step 220 can be between about 0.1 and about 10 seconds.

Once the gas flowrates are at their desired levels (e.g., steps 228, 229, 230), plasma treatment step 222 can begin. Plasma treatment step 222 includes providing a first (e.g., treatment) plasma power having a first frequency and a first power within the reaction chamber for a first plasma power pulse 224 and providing a second plasma power having a second frequency and a second power within the reaction chamber for a second plasma power pulse 226. In accordance with various examples, the second frequency is less than the first frequency.

The first frequency and/or power of step 224 can be the same or similar to the first frequency and/or power of step 212. The second frequency provided during step 226 can be less than 1 MHz or less than 500 kHz. For example, the second frequency of power provided during step 226 can be about 430 kHz. In accordance with further examples, the power provided during step 226 can additionally or alternatively be pulsed on and off and/or pulsed high and low (e.g., 20% or less than high power value). A duty ratio of the pulsed power can be between about 30 percent and about 70 percent or between about 1 and 50 percent for one or more (e.g., a plurality of) cycles. The duty ratio can be defined as a percent of plasma power on-time/(on-time+off-time); on and off can be replaced with high and low in the preceding equation. A frequency of the plurality of cycles can be between about 1 kHz and about 30 kHz. In some cases, the first frequency is ten times or more or twenty times or more than the second frequency.

In accordance with yet further examples, the second power is between about 50 W and about 1000 W or between about 50 W and about 300 W. In some cases, the first power is greater than the second power. For example, the first power can be at least 1.5 times greater or at least 2.5 times greater than the second power.

As illustrated in FIG. 2, in some cases, the step of applying the first plasma power 224 and the step of applying the second plasma power 226 overlap. In some cases, steps 224 and 226 substantially coincide (e.g., start and/or end within 0.1 seconds or less of each other). In some cases, sequences 202 and 204 can be repeated as illustrated by loop 234.

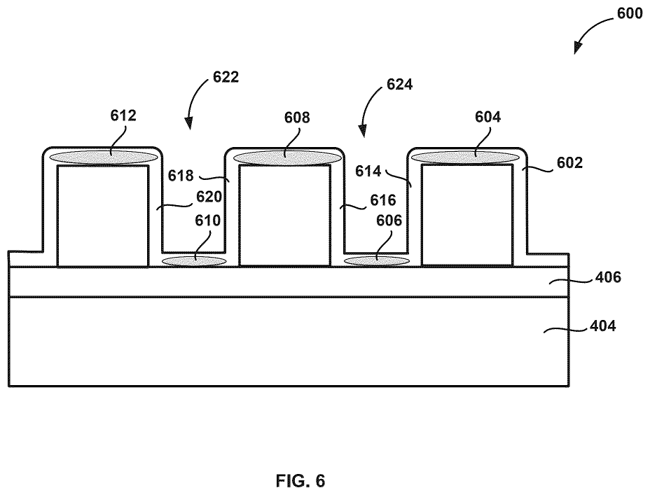

FIG. 6 illustrates a structure 600 after completion of steps 102-106 or sequence 200. Structure 600 is similar to structure 500, except structure 600 includes a topologically etch-selective material layer 602 formed from layer 502 during treatment sequence 204. Topologically etch-selective material layer 602 includes regions 604-612, of which the film quality is relatively poor, and regions 614-620, of which the film quality is relatively good or high and/or is relatively unchanged from the quality of layer 502. As illustrated, topologically etch-selective regions 604, 608, 612 can be located at a top of features 622, 624, topologically etch-selective regions 606, 610 can be located at a bottom of features 622, 624, and relatively etch-resistant regions 614-620 can be formed along (e.g., spanning) sidewalls of the respective features (e.g., sidewall 416). A thickness of layer 602 can be conformal. In this context, conformal can mean a step coverage equal to or greater than about 50%, or greater than about 80%, or greater than about 90%, or greater than about 95%, or greater than about 98%, or even above 100%. In this context, step coverage can be defined as the ratio of layer thickness along the sidewalls or bottom of a feature to the thickness of the layer in the open area without features. A density or film quality of layer 602 is not conformal. For example, etch rate (e.g., using an etch process described below) of regions 606, 610 and/or regions 604, 608, 612 can be 2, 3, 5, or more times greater than an etch rate of layer 602 in regions 614-620.

With reference again to FIG. 3, a treatment sequence 304 can be the same or similar to treatment sequence 204, except treatment sequence 304 may not be repeated and/or sequence 300 may not be repeated prior to method 100 proceeding to step 108. Sequence 300 may be particularly useful in removing overhang from material deposited during step 104.

FIG. 13 illustrates a structure 1300 after step 104 in accordance with examples of the disclosure. Structure 1300 includes a substrate 1302, a feature 1304, and a group 13 metal oxide layer 1306 deposited over feature 1304. Group 13 metal oxide layer 1306 may include an overhang 1310 in a region 1308 at a top of feature 1304. During step 106, layer 1306 and overhang 1310 are anisotropically treated, such that during step 108 (e.g., a wet etch step), more material is removed from thicker regions of overhang 1310/layer 1306, compared to non-overhang regions, resulting in a conformal layer 1312. Layer 1312 can be processed using treatment sequence 1204 and steps 106-112.

Exemplary process conditions for sequence 200 and sequence 300 are set forth below in table 1.

| Conditions | | Depo | TRT HLRF | TRT WET |
|---|---|---|---|---|
| O₂ | [slm] | Typ. ALD | — | 500:1 For |
| N₂ | [slm] | TiO | 2.0 | 120 sec |
| Ar | [slm] | | 3.0 | |
| CAR-Ar | [slm] | | — | |
| Press. | [Pa] | | 270 | |
| HRF | [W] | | 100 | |
| LRF | [W] | | 100/200 | |
| Gap | [mm] | | 12 | |
| Depo sequence | Feed | | | |
| [sec] | Purge | | | |
| | RF ON | | | |
| | Purge | | | |
| TRT sequence | Gas trans. | | 11.0 | |
| [sec] | RF ON | | 8.0/16.0 | |
| | Gas trans. | | 11.0 | |

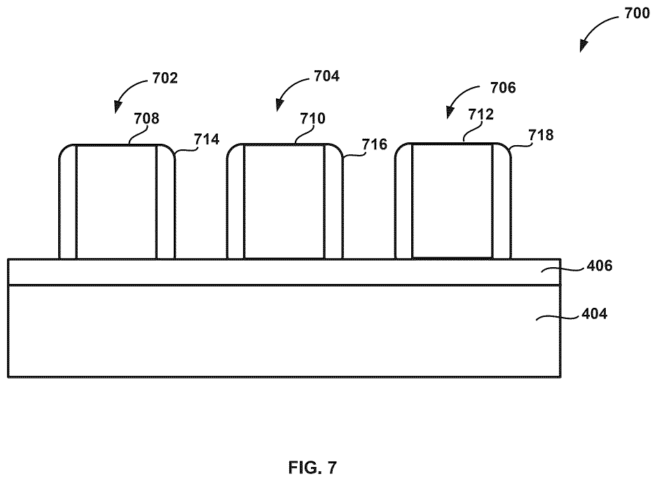

Returning to FIG. 1, once steps 104 and 106 (e.g., timing sequence 200) are complete, portions of the layer 602 (e.g., in regions 604, 606, 608, 610 and 612) are selectively removed during step 108 to form structure 700, including patterned structures 702-706, as illustrated in FIG. 7. Patterned structures 702-706 include mandrels or cores 708-712 (e.g., as described above in connection with FIG. 4) and spacers 714-718 on the respective sidewalls of mandrels/cores 708-712.

Portions of layer 602 can be selectively removed using any suitable wet or dry etch. Step 108 can include etching the topologically etch-selective material to selectively remove the topologically etch-selective material from the top and the bottom, relative to the sidewall. A wet etch process can include dilute HF, SC1 (NH₄OH and H₂O₂). For films of uniform quality (of which layer 602 is not), wet etch processes are generally considered isotropic. A dry etch process can include using activated fluorine. A reactant during the dry etch process can include, for example, NF₃ at about 50 °C to about 300 °C. Because regions 604, 606, 608, 610 and 612 are of different film quality than regions 614-620, a typically isotropic etch (for a film of uniform quality) can be used to selectively remove portions of layer 602 in regions 604, 606, 608, 610 and 612, relative to regions 614-620.

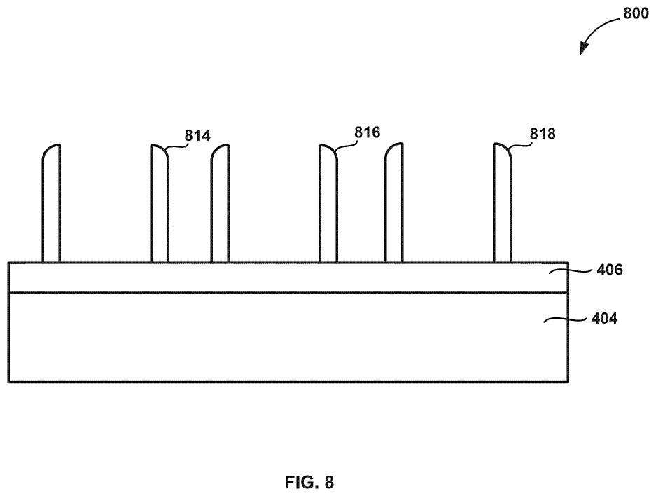

During step 110, mandrels/cores 708-712 can be removed. For example, an ashing process can be used to remove mandrels 708-712 to form device structure 800, including patterned structure 814-818, as illustrated in FIG. 8.

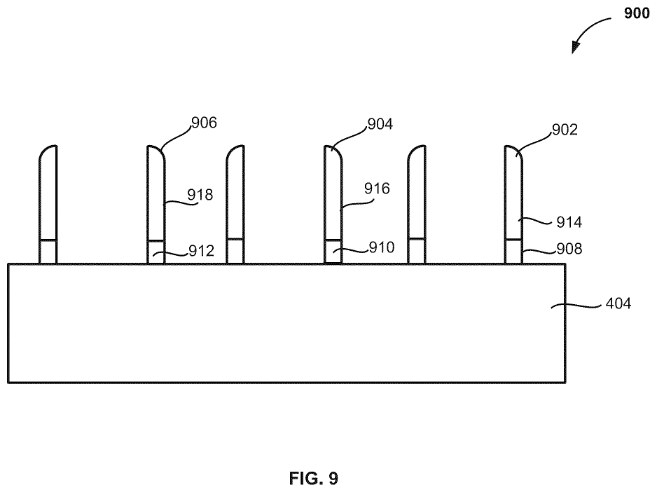

During step 112, layer 406 can be etched using patterned structures 814-818 as a templated mask to form structure 900, as illustrated in FIG. 9. Structure 900 includes bulk material/substrate 404 and patterned structures 902-906 formed thereon. Structures 902-906 include regions 908-912 that include material from layer 406 and regions 914-918 that include spacer material (e.g., a group 13 metal oxide). Any suitable etch process can be used to form structures 902-906 and will generally depend on the composition of layer 406.

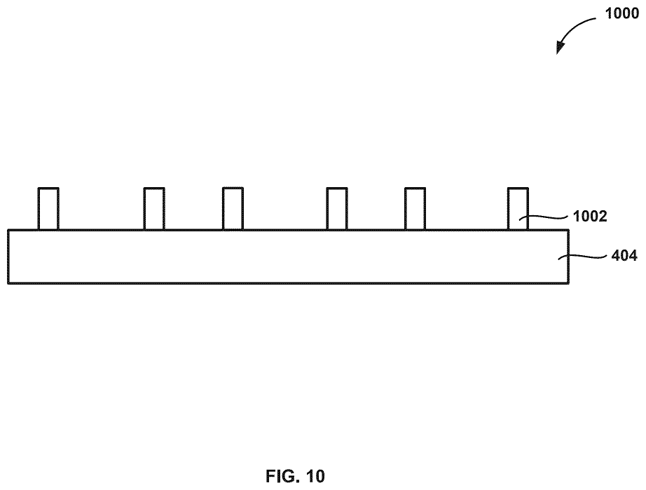

Finally, although not separately illustrated in FIG. 1, any remaining spacer material can be removed using a suitable etch to form structure 1000 illustrated in FIG. 10. Structure 1000 includes features 1002 formed of material from layer 406.

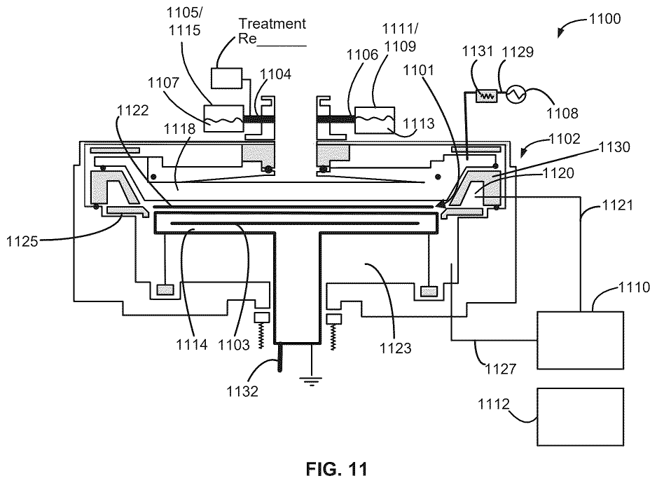

A reactor system 1100 in accordance with exemplary embodiments of the disclosure is illustrated in FIG. 11. Reactor system 1100 can be used to perform one or more steps or substeps as described herein and/or to form one or more structures or portions thereof as described herein.

Reactor system 1100 includes a pair of electrically conductive flat-plate electrodes 1114, 1118 in parallel and facing each other in an interior 1101 (reaction zone) of a reaction chamber 1102. A plasma can be excited within reaction chamber 1102 by applying, for example, plasma power from plasma power source(s) (i.e., at least one power source) 1108 to one electrode (e.g., electrode 1118) and electrically grounding the other electrode (e.g., electrode 1114). Power source(s) 1108 can be coupled to electrode 1118 via a transmission line 1129 and an RF filter 1131. As noted above, power source(s) 1108 can suitably be configured to provide plasma power at a first frequency and at a second frequency, coupled to the reaction chamber. The first frequency can additionally be pulsed as described above.

A temperature regulator 1103 can be provided in a lower stage 1114 (the lower electrode), and a temperature of a substrate 1122 placed thereon can be kept at a desired temperature, such as the temperatures noted above. Electrode 1118 can serve as a gas distribution device, such as a shower plate or showerhead. Precursor gases, reactant gases, and a carrier or inert gas, if any, or the like can be introduced into reaction chamber 1102 using one or more gas lines (e.g., reactant gas line 1104 and precursor gas line 1106, respectively, coupled to a reactant source and a precursor source). For example, an inert gas and a (e.g., deposition) reactant from at least one reactant source 1115 comprising a vessel 1105 and the reactant 1107 therein can be introduced into reaction chamber 1102 using line 1104 and/or a precursor from a precursor source 1109 comprising a first vessel 1111 and a group 13 metal precursor 1113 therein, coupled to the reaction chamber, and a carrier gas (e.g., an inert gas as described above) can be introduced into the reaction chamber 1102 using line 1106. Additionally or alternatively, a treatment reactant from at least one treatment reactant source 1134 comprising a vessel 1135 and the treatment reactant 1136 therein can be introduced into reaction chamber 1102 using line 1104. Although illustrated with two inlet gas lines 1104, 1106, reactor system 1100 can include any suitable number of gas lines.

In reaction chamber 1102, a circular duct 1120 with an exhaust line 1121 can be formed within a duct plate 1130, through which gas in the interior 1101 of reaction chamber 1102 can be exhausted to an exhaust source 1110. Additionally, a transfer chamber 1123 can be provided with a seal gas line 1132 to introduce seal gas into the interior 1101 of reaction chamber 1102 via the interior (transfer zone) of transfer chamber 1123, wherein a separation plate 1125 for separating the reaction zone 1101 and the transfer chamber 1123 can be provided (a gate valve through which a substrate is transferred into or from transfer chamber 1123 is omitted from this figure). Transfer chamber 1123 can also be provided with an exhaust line 1127 coupled to exhaust source 1110. In some embodiments, continuous flow of a carrier gas to reaction chamber 1102 can be accomplished using a flow-pass system (FPS).

Reactor system 1100 can include one or more controller(s) 1112 programmed or otherwise configured to cause one or more method steps as described herein to be conducted. Controller(s) 1112 are coupled with the various power sources, heating systems, pumps, robotics and gas flow controllers, or valves of the reactor, as will be appreciated by the skilled artisan. By way of example, controller 1112 can be configured to control gas flow of a precursor, a reactant, and an inert gas into at least one of the one or more reaction chambers to form a layer on a surface of a substrate. Controller 1112 can be further configured to provide power to form a plasma—e.g., within reaction chamber 1102. Controller 1112 can be similarly configured to perform additional or alternative steps as described herein. By way of examples, controller 1112 can be configured to provide the precursor for a precursor pulse to the reaction chamber, provide at least one reactant to the reaction chamber, and provide the plasma power at the first frequency and provide the plasma power at the second frequency for a plasma pulse to form a topologically etch-selective material on a surface of a substrate.

Controller 1112 can include electronic circuitry and software to selectively operate valves, manifolds, heaters, pumps and other components included in system 1100. Such circuitry and components operate to introduce precursors, reactants, and purge gases from the respective sources. Controller 1112 can control timing of gas pulse sequences, temperature of the substrate and/or reaction chamber, pressure within the reaction chamber, and various other operations to provide proper operation of the system 1100.

Controller 1112 can include control software to electrically or pneumatically control valves to control flow of precursors, reactants, and/or purge gases into and out of the reaction chamber 1102. Controller 1112 can include modules, such as a software or hardware components, e.g., an FPGA or ASIC, which perform certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 1100, substrates, such as semiconductor wafers, are transferred from, e.g., a substrate handling area 1123, to the reaction zone 1101. Once substrate(s) are transferred to reaction zone 1101, one or more gases, such as precursors, reactants, carrier gases, and/or purge gases, are introduced into reaction chamber 1102.

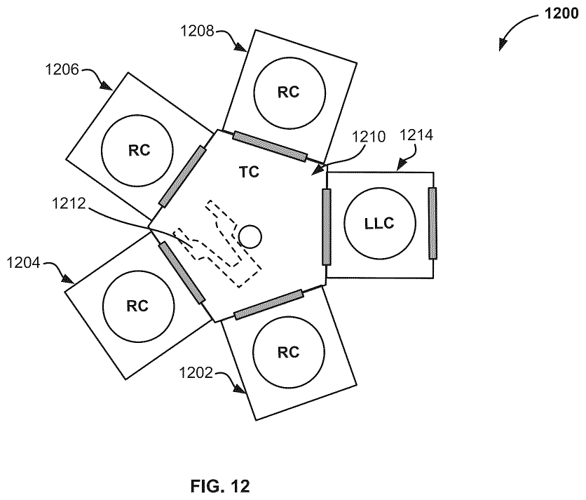

FIG. 12 illustrates a reactor system 1200 that includes a plurality of modules 1202-1208, each of which can include one or more (e.g., 1, 2, or 4) reaction chambers, such as reaction chamber 1102, described above. Modules 1202-1208 can be disposed around and/or coupled to a transfer chamber 1210 that includes a transfer tool 1212 for transferring substrates between modules 1202-1208 and a load lock chamber 1214 and between modules 1202-1208 (e.g., through transfer chamber 1210). For example, a substrate can be disposed in different chambers or modules for different steps of a method described herein. A module can include one or more controllers as described herein.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

1. A method including formation of topologically etch-selective material, the method comprising the steps of:
providing a substrate comprising at least one feature comprising a top, a bottom, and a sidewall therebetween;
conformally depositing a group 13 metal oxide over the at least one feature;
anisotropically treating the group 13 metal oxide, wherein the step of anisotropically treating comprises:
providing a nitrogen-containing reactant to a reaction chamber;
providing a first plasma power having a first frequency and a first power within the reaction chamber for a first plasma power pulse; and
providing a second plasma power having a second frequency and a second power within the reaction chamber for a second plasma power pulse,
wherein the second frequency is less than the first frequency, and
wherein the anisotropically treating the group 13 metal oxide forms the topologically etch-selective material.

2. The method of claim 1, wherein the steps of providing the first plasma power and providing the second plasma power substantially coincide.

3. The method of claim 1, wherein the first frequency is ten times or more or twenty times or more than the second frequency.

4. The method of claim 1, wherein the second frequency is less than 1 MHz.

5. The method of claim 1, wherein the first frequency is greater than 1 MHz.

6. The method of claim 1, wherein the first power is between about 50 W and about 1000 W or between about 100 W and about 500 W.

7. The method of claim 1, wherein the second power is between about 50 W and about 1000 W or between about 50 W and about 300 W.

8. The method of claim 1, wherein the first power is greater than the second power.

9. The method of claim 1, wherein the first power is at least 1.5 times greater or at least 2.5 times greater than the second power.

10. The method of claim 1, wherein the second power is pulsed on and off at a duty cycle between about 30 percent and about 70 percent for a plurality of cycles.

11. The method of claim 10, wherein a frequency of the plurality of cycles is between about 1 kHz and about 30 KHz.

12. The method of claim 1, wherein the step of conformally depositing the group 13 metal oxide comprises:
providing a group 13 metal precursor; and
providing an oxygen-containing reactant.

13. The method of claim 12, wherein the group 13 metal precursor comprises titanium.

14. The method of claim 12, wherein the steps of providing the metal precursor and providing the oxygen-containing reactant are repeated a number of times prior to the step of anisotropically treating the group 13 metal oxide.

15. The method of claim 1, further comprising etching the topologically etch-selective material to selectively remove the topologically etch-selective material from the top and the bottom, relative to the sidewall.

16. The method of claim 14, wherein the etching comprises an isotropic etch process.

17. The method of claim 1, further comprising providing a dilution gas during the steps of conformally depositing the group 13 metal oxide and anisotropically treating the group 13 metal oxide.

18. The method of claim 17, wherein a flowrate of the dilution gas during the anisotropically treating the group 13 metal oxide is less than a flowrate of the dilution gas during the conformally depositing the group 13 metal oxide.

19. A structure formed according to the method of claim 1.

20. A reactor system comprising:
a reaction chamber;
a precursor source, comprising a first vessel and group 13 metal precursor therein, coupled to the reaction chamber;
at least one reactant source coupled to the reaction chamber;
at least one treatment gas source coupled to the reaction chamber;
at least one plasma power supply, configured to provide plasma power at a first frequency and at a second frequency, coupled to the reaction chamber; and
a controller configured to:
provide the precursor for a precursor pulse to the reaction chamber;
provide at least one reactant to the reaction chamber;
provide plasma power at the first frequency during a deposition step; and
provide plasma power at the first frequency for a first plasma power period and provide plasma power at the second frequency for a second plasma power period during a treatment step to form a topologically etch-selective material on a surface of a substrate.
